(19) United States
(12) Patent Application Publication
(10) Pub. No.: US 2004/0085071 A1
(43) Pub. Date: May 6, 2004

(54) Testing apparatus

(76) Inventor: Robert Sankey, Norfolk (GB)

Correspondence Address: BAKER & HOSTETLER LLP, Washington Square, Suite 1100, 1050 Connecticut Avenue, N.W., WASHINGTON, DC, 20036, US

(21) Appl. No.: 10/286,846

(22) Filed: Nov. 4, 2002

(51) Int. Cl. G01R 31/02; G01R 31/327

(52) U.S. Cl. 324/418

(57) ABSTRACT

An apparatus for testing an electrical relay is disclosed which comprises a portable housing and an electrical testing circuit within the housing for performing a plurality of types of tests on the relay. A connector arrangement is provided for connecting the electrical testing circuit to the relay and a display is provided for displaying the results of the tests.

### FIELD OF THE INVENTION

The present invention relates to a testing apparatus and particularly, but not exclusively, to a testing apparatus for detecting faults in the operation of electrical relays.

### BACKGROUND OF THE INVENTION

At present, it is normal practice to test electrical relays by hand, for example by connecting the input terminals of the relay to a power source and confirming, either visually or by means of an electrical indicator circuit connected to the output terminals of the relay, that the relay contacts are operating. By connecting the relay to a multimeter or the like, the technician is able to measure a number of electrical properties of the relay in order to diagnose potential faults. It is a considerable disadvantage of this method that such testing by hand is time consuming and relatively complicated and relies on significant knowledge on the part of the technician as to the operating properties of the relay under test.

It would be advantageous to provide an apparatus which allows the comprehensive evaluation of a given electrical relay both quickly and accurately and without relying on any pre-existing knowledge on the part of the technician.

### SUMMARY OF THE INVENTION

It is an object of the present invention to provide such an apparatus which is both easy to use and highly portable.

According to one aspect of the present invention, therefore, there is provided an apparatus for testing an electrical relay, the apparatus comprising: a portable housing; an electrical testing circuit inside said portable housing for performing a plurality of different types of electrical tests on said electrical relay; a connection arrangement connected to said electrical testing circuit for connecting said electrical testing circuit to said electrical relay; and a display for displaying the results of said tests.

Advantageously, said electrical tests may include any of the following tests:

Short Circuit test; Pull-in Current test;

Contact Release Current test;

Normally Open (NO)/Normally Closed (NC) Contact Voltage Drop test; and

Relay Cycle test.

Conveniently, the housing is provided with a plurality of actuating switches, such as push button switches, for selecting which test is to be performed on the relay.

Preferably, the display comprises a digital multimeter or the like having an LCD display or similar which is arranged to display one or more properties of the relay under test. The display can however use LEDs to display the results. The apparatus may be provided with an information source containing the technical specification of the type of relay under test. The technician may therefore be able to compare the results displayed by the display with the values contained in the information source to determine whether the relay under test is functioning correctly. Advantageously, therefore, the determination of whether a particular relay is functioning correctly does not require the foreknowledge of the technician either of the relay or the apparatus itself.

### BRIEF DESCRIPTION OF THE DRAWINGS

FIG. 1 is a first perspective view of a preferred form of apparatus according to an embodiment of the invention;

FIG. 2 is a second perspective view of the apparatus of FIG. 1;

FIG. 3a is a perspective view of a connecting lead for connecting a relay under test to the apparatus of FIG. 1;

FIG. 3b illustrates the electrical connections within the connecting lead of FIG. 3a;

FIG. 4 is a block diagram showing the electrical connections in the apparatus of FIG. 1;

FIG. 5 illustrates the electrical connections within the apparatus of FIG. 1 in more detail;

FIG. 6 is a circuit diagram showing polarity protection circuitry used in the apparatus of FIG. 1;

FIGS. 7a-7c are electrical circuit diagrams illustrating the connection of a digital multimeter or the like to the apparatus of FIG. 1;

FIG. 8 is a circuit diagram showing circuitry for performing a first test on a relay or the like;

FIG. 9 is a circuit diagram showing circuitry for providing a 24 volt supply to the circuit of FIG. 10;

FIG. 10 is a circuit diagram showing a circuitry for performing a second test on a relay;

FIG. 11 is an electrical circuit diagram showing circuitry for performing a third test on a relay;

FIG. 12 is an electrical circuit diagram showing a first part of a circuit for performing a fourth test on a relay;

FIG. 13 is a circuit diagram showing a second part of a circuit for performing a fourth test on a relay;

FIG. 14 is a circuit diagram showing circuitry for performing fifth and sixth tests on a relay;

FIG. 15a is a perspective view of a dummy test relay for testing the apparatus of FIG. 1 and the connecting lead of FIG. 3; and

FIG. 15b is an electrical circuit diagram illustrating the connections within the dummy test relay of FIG. 15a.

### DESCRIPTION OF EMBODIMENTS OF THE INVENTION

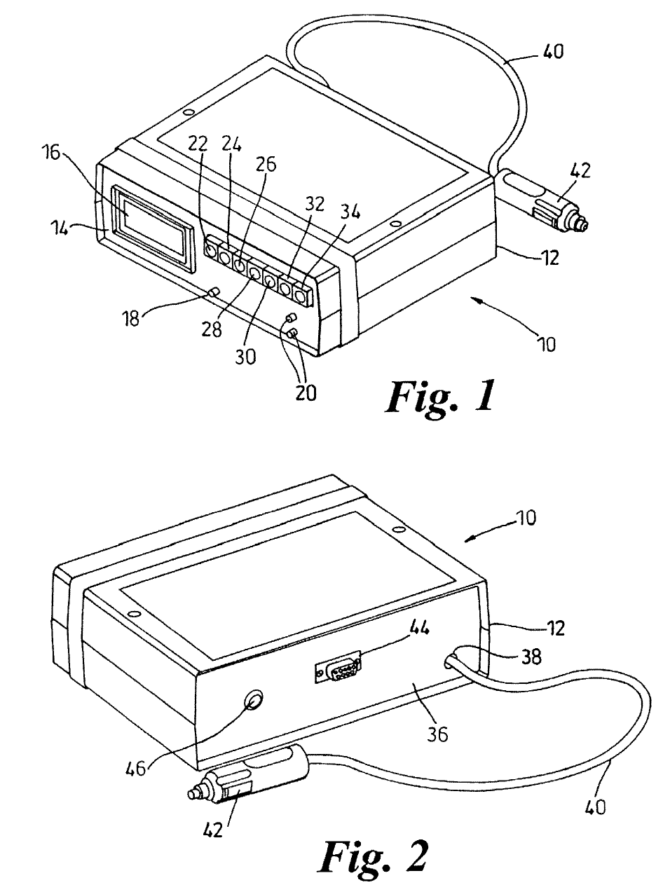

Referring firstly to FIGS. 1 and 2, a preferred form of apparatus according to an embodiment of the invention is shown generally at 10. The apparatus 10 comprises a housing in the form of generally box-shaped casing 12. A front face 14 of the casing 12 is provided with an LCD display 16, a single red LED 18, a pair of yellow LED's 20 and a plurality of push button switches 22-24. The purpose of these features is described below.

A rear face 36 of the casing 12 is provided with an aperture 38 through which extends a power cable 40 for supplying power to the apparatus. A power adapter or plug 42 is connected to the free end of the cable 40 for insertion into a suitable power outlet, for example the cigarette lighter socket on an automobile, for supplying power to the apparatus. A connection arrangement, in the form of a 9-pin D-type socket 44 is mounted on the rear face 36 of the apparatus 10 for connecting a relay to be tested to the apparatus as described below. The rear face 36 is also provided with a socket 46 for connecting the apparatus to a PC or other external computer or data collector.

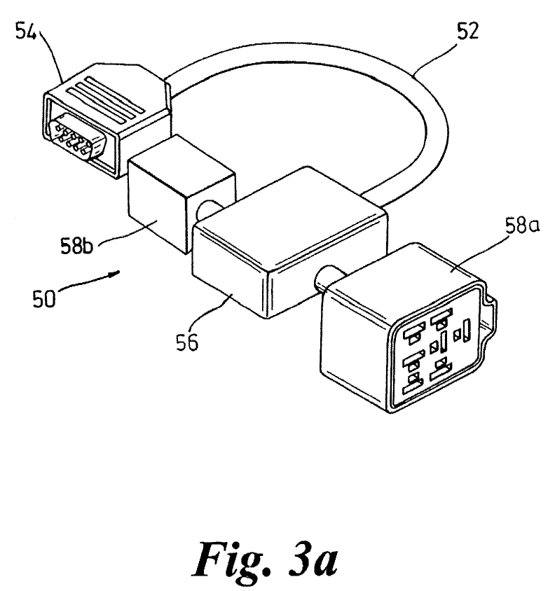

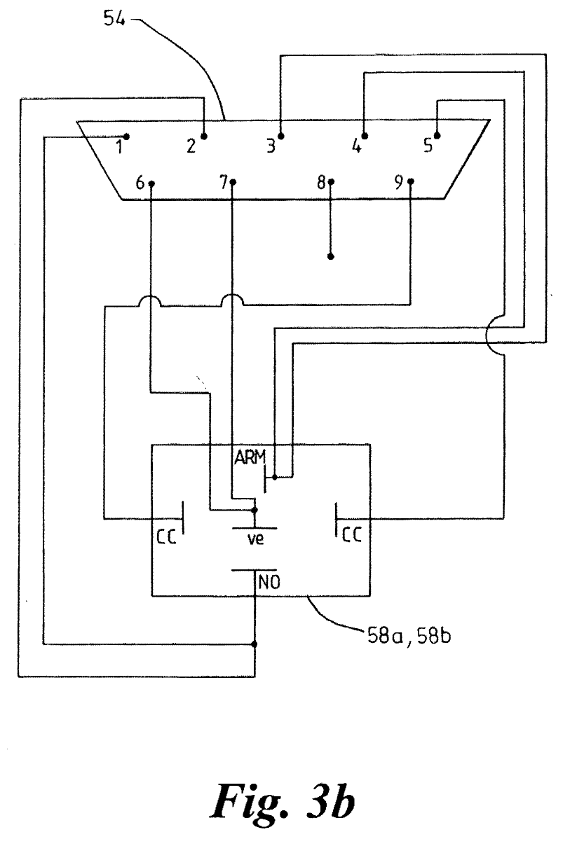

In FIG. 3a a connecting lead for connecting a relay to be tested to the apparatus of FIGS. 1 and 2 is shown generally at 50. The connecting lead 50 comprises a length of multi-core cable 52 having at one end, a 9-pin D-type plug 54 suitable for insertion in the D-type socket 44 on the rear face 36 of the testing apparatus. The other end of the multi-core cable 52 is connected to a splitter or patch unit 56 which connects each of the core wires in the cable 52 to one of the terminals of respective relay connection sockets 58a, 58b. In FIG. 3a, the patch unit 56 is provided with two relay connection sockets 58a, 58b thereby to allow connection and testing of two different types of relays but it will be appreciated that a greater or lesser number of relay connection sockets may be provided.

FIG. 3b shows the internal connections between the pins of D-type plug 54 and the terminals of the relay connection sockets 58a, 58b by the core wires of the multi-core cable 52. Pins 1 and 2 of the D-type plug 54 are connected by respective core wires to the normally open (NO) contact terminal of each relay connection socket but the core wires remain separate and unconnected until a point at or close to the contact terminal itself. The reasons for this are described below. Pins 3 and 4 of the D-type plug 54 are connected by respective core wires to the armature pin of the relay connection socket but again the two core wires remain separate and unconnected until a point at or close to the armature terminal itself. Pins 6 and 7 of the D-type plug 54 are connected by respective core wires to the normally closed (NC) contact terminal of the relay connection socket. Once again, the two core wires are not joined until a position at or close to the contact terminal itself. Pins 5 and 9 of the D-type plug 54 are connected to respective coil pins of the relay connection socket while pin 8 is connected to an auxiliary pin (not shown) of the relay connection socket.

The schematic block diagram of FIG. 4 represents the basic interconnections between the apparatus 10 and the connecting lead 50 and relay connection sockets 58a, 58b. The apparatus 10 comprises a plurality of separate circuits 100-600 which are designed to perform a number of electrical tests on a relay or the like. Each of these circuits, the arrangements of which will be described in more detail below, are connected to the D-type socket 44 on the rear face 36 of the apparatus via a switching matrix consisting of the switches 22-34 on the front face of the apparatus. Each push button 22-34 selectively connects a respective one of the circuits 100-600 to the D-type socket 44 in a predetermined manner, described below. Thus, when the D-type plug 54 is inserted into engagement with the D-type socket 44, any one of the circuits 100-600 can be selectively connected to the relay, for testing thereof, by operation of the appropriate push button switch 22-34.

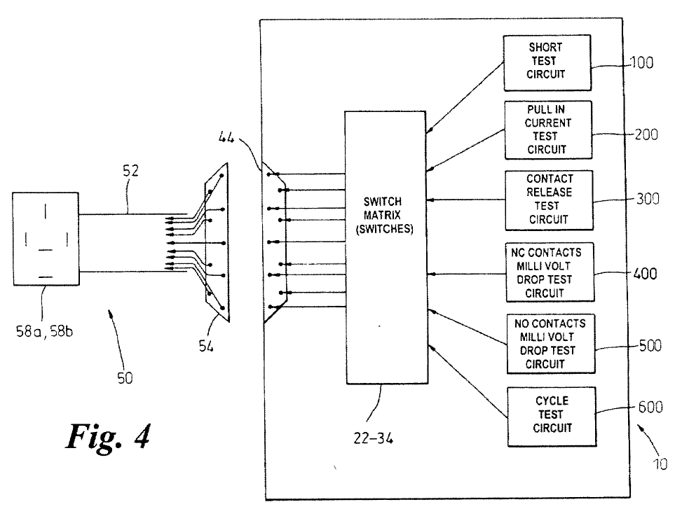

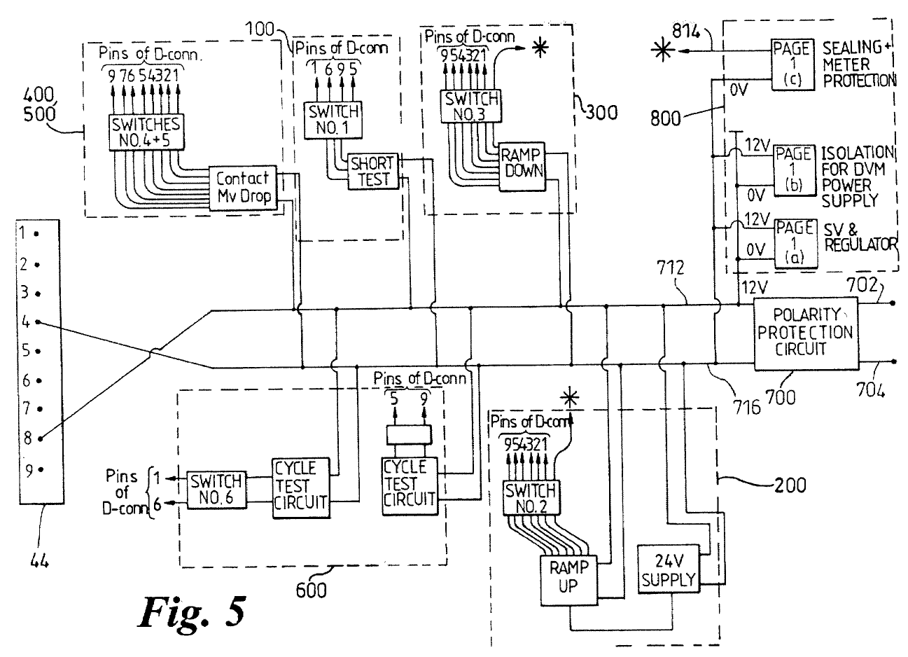

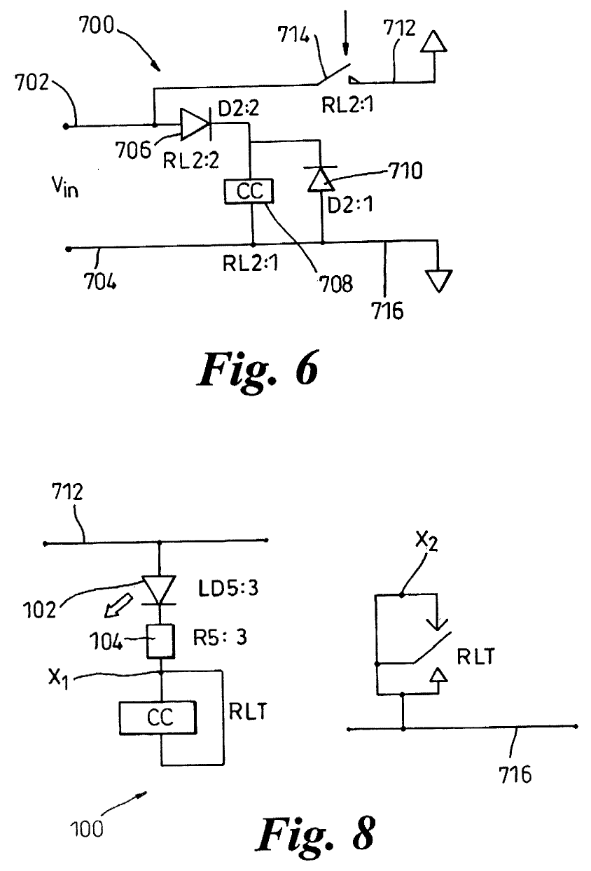

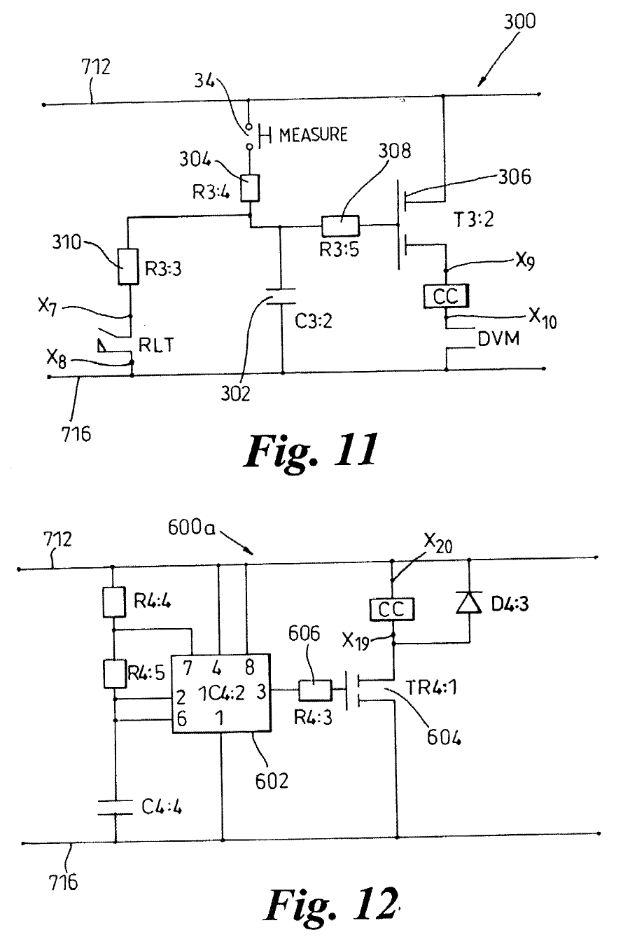

The apparatus and the connections is shown in more detail in FIG. 5 which additionally illustrates the connection of a polarity protection circuit 700 and a digital multimeter 800. In fact, the digital multimeter 800 (hereafter referred to as “DVM 800”) is required only to measure voltage and current and the term “multimeter”, usually given to devices capable of measuring additional electrical properties, is used only for convenience and is not intended to be limiting. The circuits 100-600, 800 are connected in parallel to the output of the polarity protection circuit 700 and all are shown in more detail in FIGS. 6 to 14.

FIG. 6 shows a circuit diagram for the polarity protection circuit 700 which protects the other circuits 100-600 and DVM 800 in the apparatus 10 from reverse polarity connection to a power supply. The polarity protection circuit 700 consists of a positive input line 702 and an ground or zero volt input line 704 which are directly connected to the positive and negative terminals of the power plug 42 shown in FIG. 2. A diode 706 and the coil CC of a power relay 708 are connected in series between the positive input line 702 and the zero volt input line 704. The diode 706 is forward biased with respect to the power supply. A second diode 710 is connected across the coil CC of the power relay 708 in a reverse biased direction for protection against back EMF generated by the coil.

The output of the polarity protection circuit is formed by a positive output line 712 (hereafter referred to as “positive supply rail 712”) and a zero volt output line 716 (hereafter referred to as “ground rail”). The positive supply rail 712 is connected to the positive input line 702 via a switch 714 formed by the armature and normally open (NO) contacts of the power relay 708. The ground rail 716 is connected directly to the zero volt input line 704.

In operation, if the polarity protection circuit 700 is correctly connected to the power supply via power connector 42 i.e. with the positive input line 702 connected to the positive terminal of the supply and the zero volt input line 704 connected to the negative terminal of the supply, then current will flow from the positive input line 702 and through the coil CC of the power relay 708 to the zero volt input line 704 via the forward biased diode 706. When current passes through the coil CC, this activates the armature 714 of the relay 708 which closes, thus connecting the positive input line 702 to the positive supply rail 712.

If the polarity of the power supply to the polarity protection circuit 700 is reversed, then no current will flow through the coil CC of the power relay 708 since the diode 706 is reverse biased. The contacts 714 of the relay 708 will therefore not close and the positive supply rail 712 will remain unconnected to the positive input line 702. This circuit therefore ensures that power having the correct polarity is applied to the circuits 100-600 and DVM 800 of the apparatus at all times.

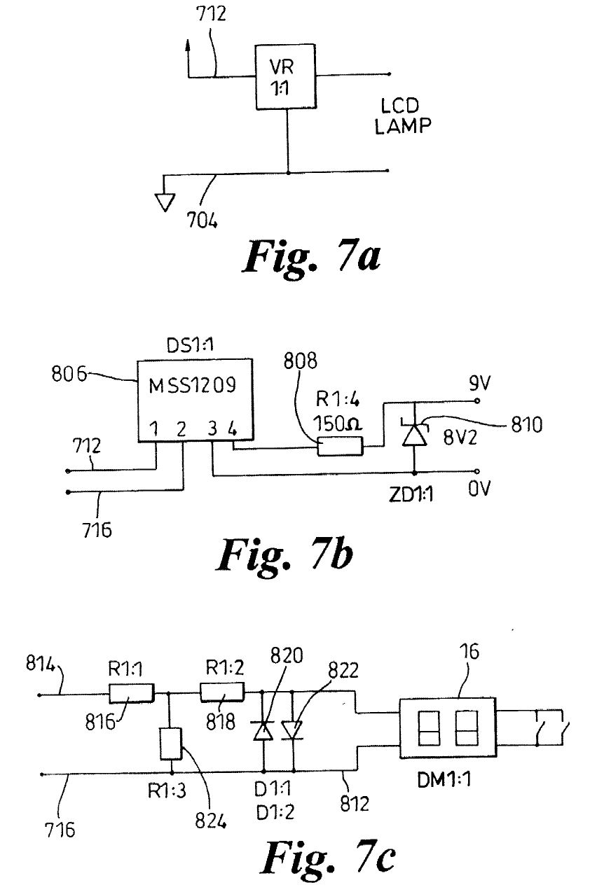

FIGS. 7a to 7c, in conjunction with FIG. 5, shows the circuitry for connecting the DVM 800 to the apparatus 10. The DVM 800 has an LCD display (shown at 16 in FIG. 1) which, in the described embodiment, is backlit by means of a lamp (not shown) requiring a 5 volt power supply. FIG. 7a illustrates the connection of a suitable power supply, in the form of a 5 voltage fixed regulator, to the LCD lamp.

FIG. 7b shows the circuitry for providing power to the DVM itself. In the described embodiment, the DVM 800 requires an isolated 9 volt supply and is therefore connected to the positive supply rail 712 and ground rail 716 via an isolator 806. The outputs from the isolator 806 are connected to the DVM 800 via a resistor 808. The voltage drop over the resistor reduces the output voltage from the isolator 806 from 12 volts to the required 9 volts. A Zener diode 810 is reverse biased across the 9 volt input to the DVM 800.

FIG. 7c illustrates circuitry for scaling and meter protection for the DVM 800. The DVM consists of a LCD display 16 which has a ground input line 812, connected directly to the ground rail 716, and a sensing input line 814 comprising two resistors 816, 818 in series. Two diodes 820, 822 are connected in anti-parallel across the sensing input line 814 and the ground input line 812, and a third resistor 824 is connected between the ground input line 812 and the input sensing line 814 at a point between the two resistors 816, 818. Such an arrangement is well known.

In addition, a resistor (not shown) is connected between the sensing input line 814 and the ground input line 812 of the DVM 800. This resistor acts as a current shunt to enable the DVM to measure current and is preferably a 1 Ohm resistor.

The apparatus according to the invention is designed to perform a plurality of types of electrical tests on a relay and in the preferred embodiment shown in the drawings, the apparatus is arranged to perform six different tests on a connected relay. These tests, and the circuitry for performing them, are now described in turn.

Relay Short Test

This test is designed to confirm whether the relay has a short circuit between parts of the coil and the armature assembly, including the relay contacts. FIG. 8 is a circuit diagram of the Relay Short Test circuit 100 shown in FIG. 4. The circuit 100 consists of an LED 102, the anode of which is connected to the positive supply rail 712 via a current limiting resistor 104. The cathode of the LED 102 is connectable, via the “short button” switch 22, pins 5 and 9 of the engaged D-type plug/socket 44, 54 combination (hereafter referred to as the D-connector 44, 54) and the relay connection socket 58a, 58b, to both ends of the conductor coil CC of the relay under test (shown in the drawings as RLT). The switch 22 also operates to connect the NO and NC contacts of the relay RLT to the ground rail 716 via pins 1 and 6 of the D-connector 44, 54. The armature of the relay RLT is directly connected to ground via pin 4 of the D-connector at all times.

To test for a short circuit in the relay RLT, the user presses the switch 22 on the front panel of the apparatus 10. This connects the positive supply rail 712 to the coil CC of the relay RLT via the LED 102 and current limiting resistor 104, and also connects the NO and NC contacts of the relay RLT to the ground rail 716. In the event of an internal short in the relay RLT between any part of the coil CC and the armature assembly, including the relay contacts, current will flow from the positive supply rail 712 through the LED 102, current limiting resistor 104, through the short between the coil and the armature assembly of the relay RLT to the ground rail 716. This current flow causes the LED 102 to illuminate, and in the preferred embodiment, the LED 102 is a flashing LED which flashes at a rate of 1.5 Hz. Clearly, if there is no such short between the coil and armature assembly of the relay RLT, then no current will flow through the LED 102.

Pull-In Current Test

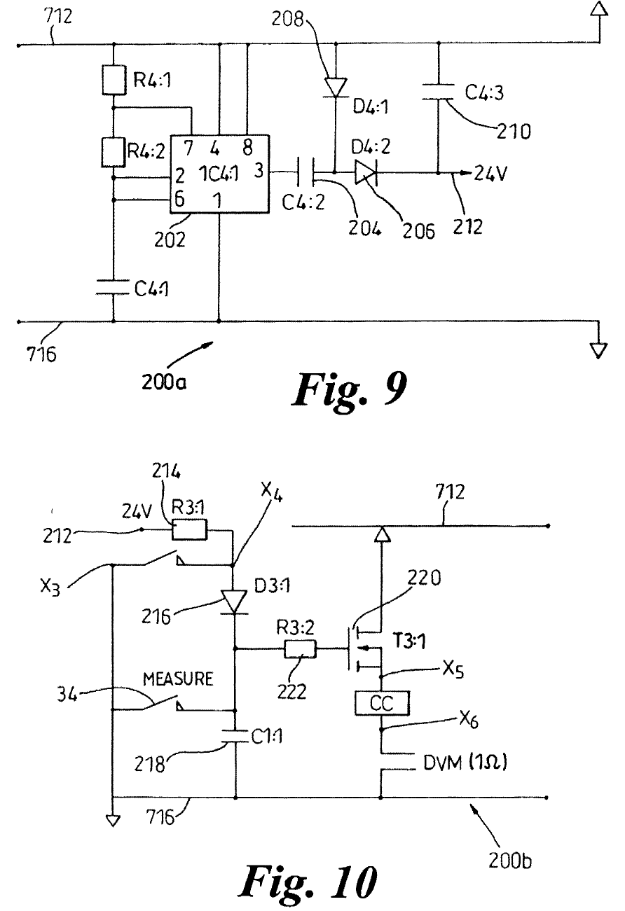

This test determines the current that is required to operate the relay, i.e. to cause the armature of the relay RLT to move from the NC contact to the NO contact. FIGS. 9 and 10 are circuit diagrams of the circuitry for the Pull-in Current Test circuit 200.

In the preferred embodiment, this test requires the use of a 24 volt supply and FIG. 9 illustrates circuitry 200a for generating such a supply. The circuit of FIG. 9 is conventional in form and includes an integrated circuit 202, in the form of a 555 timer, which is arranged to generate a substantially square wave, alternating voltage. This alternating voltage is applied to a conventional voltage doubler consisting of a capacitor 204, first and second diodes 206, 208 and a smoothing capacitor 210. The voltage doubler operates in a conventional manner with each diode 206, 208 acting as rectifiers. The rectifiers separately rectify alternate half cycles of the alternating voltage generated by the 555 timer 202 and then sum the two outputs of the diodes 206, 208. Thus, with a 12 volt supply from the positive supply rail 712, the circuit 200a generates an approximately 24 volt output which is supplied to an output line 212 for supply to the circuit of FIG. 10.

FIG. 10 shows circuitry 200b which performs the Pull-in Current Test on the Relay RLT.

The 24 volt output line 212 of FIG. 9 is connected to the ground rail 716 via a resistor 214, a diode 216 and a capacitor 218. These are connected in series between the 24 volt output line 212 and the ground rail 716. The anode of the diode 216 is also connectable at position X₄ to the NO contact of the relay RLT via the switch 24 and pin 1 of the D-connector 44, 54.

The armature of the relay RLT is connectable at position X₃ to the ground rail 716 via switch 24 and pin 4 of the D-connector 44, 54.

The cathode of diode 216 is connected to the ground rail 716 via the “measure” switch 34 and to the gate electrode of a 3-terminal field effect transistor (FET) via a resistor 222 which is provided to reduce or eliminate parasitic oscillation. The drain of the FET 220 is connected directly to the positive supply rail 712 whilst the source is connectable at position X₅ to one end of the coil CC of the relay RLT via the switch 24 and pin 9 of the D-connector 44, 54. The other end of the coil CC of the relay RLT is connectable at position X₆ to the input sensing line 814 of the DVM via the switch 24 and pin 5 of the D-connector, and from the DVM to the ground rail 716.

It will be appreciated that the capacitor 218, being directly connected to the permanent 24 volt output line 212 via the resistor 214 and diode 216, will initially be charged. In order to test the Pull-in current for the relay RLT, therefore, the user presses the switch 24 to connect the circuit 200 to the relay RLT in the manner described above and then presses the measure button 34 which discharges the capacitor 218 to ground. When the measure button 34 is released, the capacitor Cl begins to charge from the 24 volt output line 212. As the capacitor 218 charges, the increasing voltage over the capacitor is applied to the gate electrode of the FET 220 and causes the FET gradually to turn on. This gradual switching of the FET 220 causes as gradual increase in current to flow between the drain and source of the FET 220 and thus a gradual increase in the current through the coil CC of the relay RLT. The current through the coil CC of the relay RLT is continuously monitored by the DVM 800. When the current reaches a level sufficient to energise the coil, the NO contacts of the relay close and the 24 volt output line 212 is effectively shorted to the ground rail 716 via the relay contacts. The capacitor 218 is thus effectively disconnected from the 24 volt output line 212 and the charge on the capacitor 218 remains substantially constant. There is negligible discharging of the capacitor 218 at this time, either via the measure switch 34 (since this is open circuited) or via the FET 220 (which has an input impedance in the order of Gigaohms). With the voltage applied to the gate electrode of the FET 220 effectively clamped by the capacitor 218, the current through the source and drain of the FET and hence through the coil of the relay remains substantially constant. This constant current is measured and displayed by the DVM 800 and represents the minimum current required to energise the relay.

If it is required to remeasure the pull-in current of the relay RLT, the user merely presses the measure switch 34 which, as described above, discharges the capacitor 218 to ground. This turns off the FET 220 and the relay is de-energised so that the contacts open. When this occurs, the capacitor is again supplied with the 24 volt supply and begins to charge. The process is therefore repeated as above.

Contact Release Test

This test determines the current at which the relay de-energises. FIG. 111 shows the circuitry for the Contact Release Test circuit 300. The circuit 300 comprises a charging capacitor 302 which is connected at one electrode to the positive supply rail 712 via the measure switch 34 and a resistor 304. The other electrode of the capacitor is connected directly to the ground rail 716. The first electrode of the capacitor 302 is connected to the gate electrode of a FET 306 via a resistor 308. The FET 306 has its drain connected to the positive supply line 712 and its source connected to the ground rail 716 via the coil CC of the relay RLT and the DVM 800 in the manner described in connection with FIG. 10.

The circuit is thus connected at position X₉ to one end of the coil CC of the relay RLT via the switch 26 and pin 9 of the D-connector 44, 54 and to the other end of the coil CC at position X₁₀ via the switch 26 and pin 5 of the D-connector 44, 54. The capacitor 302 is also connected via a resistor 310 at position X₇ to the NO contact of the relay RLT via the switch 26 and pin 1 of the D-connector 44, 54. The armature of the relay RLT is connected to the ground rail 716 also via the switch 26 and pin 4 of the D-connector 44, 54.

In operation, the capacitor 302 is initially discharged so that the FET 306 is switched off. Therefore no current flows through the coil CC of the relay RLT and the contacts of the relay are open. To perform the contact release test, the user presses the measure switch 34 which connects the capacitor to the positive supply rail 712 via resistor 304 and causes the capacitor 302 to charge up and the FET 306 to turn on. Current is thus allowed through the coil CC of the relay RLT and when this reaches a value sufficient to energise the coil, the contacts of the relay close.

When the contacts of the relay RLT close, the capacitor 302 begins to discharge to ground through resistor 310 and the reducing charge on the capacitor 302 causes the FET 306 gradually to switch off. As a consequence, the current through the coil CC of the relay RLT gradually reduces until a level of current is reached whereby the coil de-energises and the contacts of the relay open. At this point, the capacitor 302 stops discharging through resistor 310 and cannot recharge since the measure button switch 34 is still open. In addition, the capacitor 302 is unable to discharge through the FET 306 since its impedance is in the order of Gigaohms.

The charge on the capacitor 302 thus remains fixed and the FET 306 remains at its instantaneous “semi-on” state such that a constant current flows through the coil CC of the relay RLT. This current is representative of the current at which the relay de-energises and is measured and displayed by the DVM 800.

Normally Open/Normally Closed Contact Voltage Drop Test

This test checks the condition of the contacts of the relay and the internal wiring and connections and will highlight contact contamination or any foreign bodies present and any other contact abnormalities. FIG. 14 shows circuitry 400, 500 for the normally open and normally closed contacts voltage drop test. In this circuit, a first resistor 402 is connected between the positive supply rail 712 and, at position X₁₁, to the NC contact of the relay RLT via the switch 28 and pin 6 of the D-connector 44, 54. The circuit 400, 500 also provides for the connection, at position X₁₅, of the NC contact of the relay RLT to the input sensing line 814 of the DVM 800 via the switch 28 and pin 7 of the D-connector 44, 54.

A second resistor 404 is connected between the positive supply rail 712 and, at position X₁₆, to the NO contact of the relay RLT via the switch 30 and pin 1 of the D-connector 44, 54. The circuit also provides for the normally open contact of the relay RLT to be connected to the input line 814 of the DVM at position X₁₄ via the normally open voltage drop button 30 and pin 2 of the D-connector 44, 54. The armature of the relay RLT is connectable to the ground input line 812 of the DVM 800 at position X₁₃ via either the normally closed voltage drop button 28 or the normally open voltage drop button 30 and pin 3 of the D-connector 44, 54. The armature is also connectable to the ground rail 716 at position X₁₂ via either the normally closed voltage drop button 28 or the normally open voltage drop button 30 and pin 4 of the D-connector.

The circuit 400 also provides for the coil CC of the relay RLT to be connected to the positive supply rail 712 at position X₁₇ via the normally open voltage drop button 30 and pin 5 of the D-connector 44, 54 and to the ground rail 716 at position X₁₈ via the normally open voltage drop button 30 and pin 9 of the D-connector 44, 54.

To measure the voltage drop across the NC contact of the relay RLT, the user presses the switch 28 which connects the NC contact of the relay RLT both to the positive supply rail 712 via resistor 402 and to the sensing input line 814 of the DVM 800. The armature contact of the relay RLT is also connected to the ground input line 812 of the DVM 800 and to the ground rail 716. The DVM 800 is thus able to measure the potential at the NC contact and therefore the potential difference or voltage drop between the armature and the NC contact.

As described above, pins 1 and 2 of the D-connector are connected together as close as possible to the NC contact of the relay RLT to ensure that the potential measured by the DVM 800 is not effected by the resistance of the wires connecting the D-connector 44, 54 to the relay RLT. For example, if pins 6 and 7 of the D-connector were joined at the D-connector itself, then the voltage drop measured by the DVM 800 would include the voltage drop of the core wire leading from pin 6 of the D-connector to the normally closed contact thus giving an inaccurate reading.

Measurement of the NO contact voltage drop is achieved in a similar way. In this instance the technician presses the switch 30 which connects the coil CC of the relay RLT to the positive supply rail 712 and the ground rail 716 thus energising the relay and closing the NO contacts. In addition, operation of the switch 30 connects the NO contact of the relay RLT both to the positive supply rail 712 via resistor 404 and to the sensing input line 814 of the DVM 800 and also connects the armature of the relay RLT to both the ground rail 716 and the ground input line 812 of the DVM.

Current therefore flows through the resistor 404 and through the NO contacts of the relay RLT to ground. The potential at the NO contact is measured by the DVM and thus the potential difference or voltage drop between the armature and the NO contact can be determined.

Cycle Test

This test removes mild contamination from the relay contact surfaces. If either contact voltage drops are high, the cycle function may eliminate this problem. This test also allows the technician to verify the contact function over a period of time. Ideally, this test should be run for at least 30 seconds to clear contaminates.

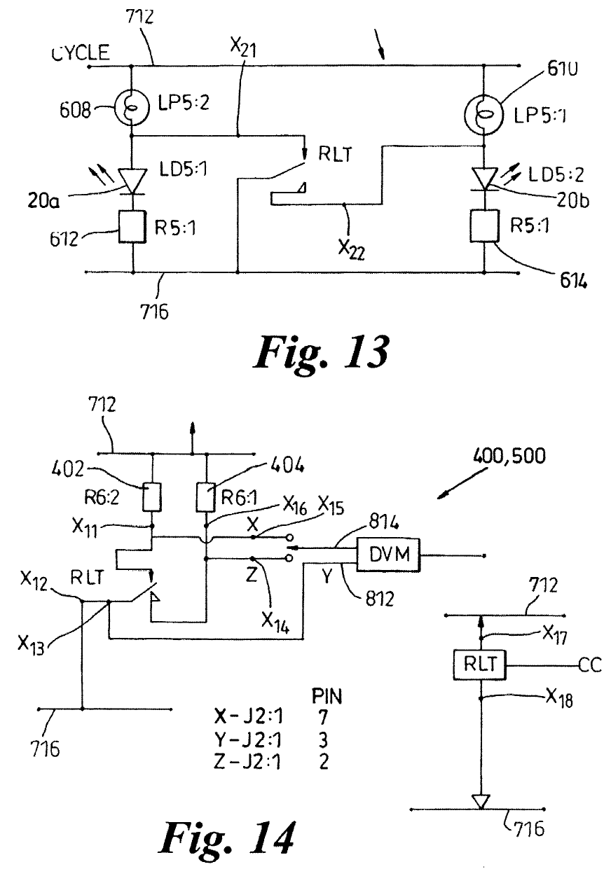

FIGS. 12 and 13 show circuitry for the cycle test circuit 600. In this test, the relay is energised and de-energised intermittently to cycle the contacts of the relay repeatedly between open and closed positions. FIG. 12 shows the circuit 600a for an oscillator for intermittently energising and de-energising the coil of the relay RLT. The circuit 600a is conventional and comprises a 555 timer 602 arranged to output a square wave alternating voltage. The output of the timer 602 is connected to the gate electrode of a FET 604 via a resistor 606. The drain electrode of the FET 604 is connectable at position X₉ to one end of the coil CC of the relay RLT via the switch 32 and pin 5 of the D-connector 44, 54 while the source of the FET 604 is directly connected to the ground rail 716. The other end of the coil CC of the relay RLT is connectable at position X₂₀ to the positive supply rail 712 via the switch 32 and pin 9 of the D-connector 44, 54.

FIG. 13 shows a second part 600b of the cycle test circuit consisting of two incandescent light bulbs 608, 610 installed within the housing 12 of the apparatus. The first bulb 608 is connected between the positive supply rail 712 and the NO contact of the relay RLT via the switch 32 and pin 1 of the D-connector 44, 54. The bulb 608 is also connected to the ground rail 716 via a first one 20a of the yellow LEDs 20 and a current limiting resistor 612.

The second bulb 610 is connected between the positive supply rail 712 and the NC contact of the relay RLT at position X₂₂ via the switch 32 and pin 6 of the D-connector 44, 54. The second bulb 610 is also connected to the ground rail 716 via a second one 20b of the LEDs 20 and a protective resistor 614.

In operation, when the switch 32 is pressed by the user, the coil CC of the relay RLT is connected to the oscillator circuit 600a of FIG. 12 which begins to energise and de-energise the relay coil. The armature of the relay RLT alternates between NO and NC positions.

Referring to FIG. 13, when the armature of the relay is in the NC position (i.e., the relay is temporarily de-energised by the oscillator), current flows through the first bulb 608 and through the normally closed contacts of the relay RLT to ground. Little or no current flows through the first LED 20a, owing to the presence of the resistor 612, which remains switched off. However, current will also flow through the second bulb 610 to ground through the second LED 20b which therefore illuminates.

When the relay coil is energised by the oscillator circuit 600a, the contacts of the relay RLT switch over so that the armature is in the NO position. In this instance, current will flow through the second bulb 610 and through the short provided by the closed contacts of the relay RLT to ground. Clearly, no current will flow through the second LED 20b, since there is no voltage over the LED 20b, which therefore remains off. However, current will also flow through the bulb 608 to ground via the first LED 20a which therefore illuminates.

It can be seen that as the relay cycles between NC and NO positions, the first and second yellow LEDs 20a and 20b turn on and off alternately. The purpose of the incandescent bulbs is to provide a surge of current through the relay contacts to simulate a realistic circuit load as would be experienced in normal use of the relay.

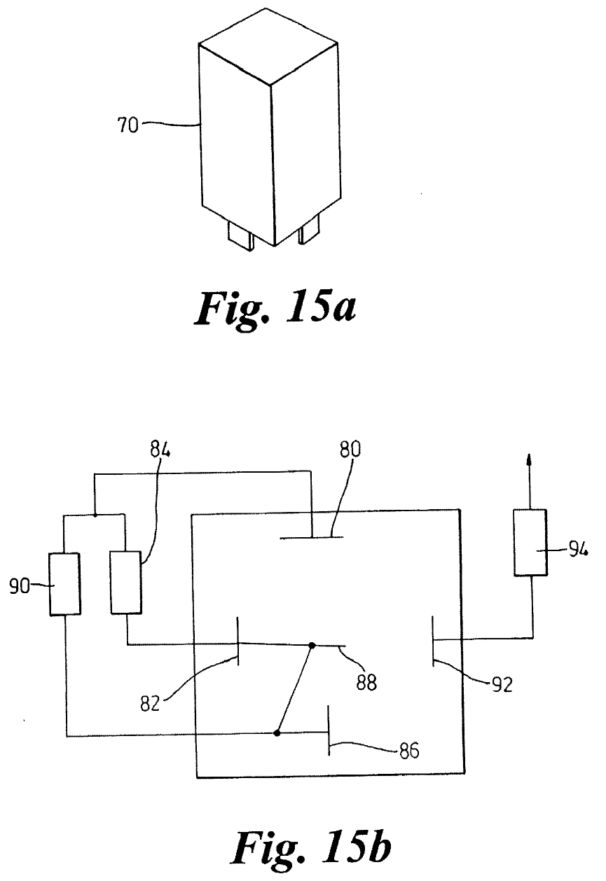

The apparatus of the invention may optionally be provided with means for testing the or each of the sockets 58a, 58b to which the relay RET is connected. As shown in FIG. 15a, the testing means takes the form of a dummy relay 70 which may be plugged into the test sockets 58a, 58b to determine their integrity.

The connections to the terminals of the dummy relay of FIG. 15a are shown in FIG. 15b. The armature pin 80 of the dummy relay is electrically connected to one of the coil pins of the dummy relay 82 via a resistor 84. The coil pin 82 of the dummy relay is also connected to the NO contact pin of the dummy relay via the NC contact pin 88. The armature pin 80 is also connected directly to the NO contact pin 86 via second resistor 90. The second coil pin 92 is supplied with 12 volts, which is obtained from pin 8 of the D-connector 44, 54 by means of a suitable connecting plug (not shown) or a socket on the splitter, via a third resistor 94.

When the dummy relay 70 is inserted in the test socket 58a, 58b, the user selects each of the above described tests in turn by pressing the appropriate switches and monitors the readings on the LCD display 16 of the DVM 800. The arrangement of connections and resistors within the dummy relay 70 is designed to generate predetermined readings on the DVM 800. If the actual readings on the DVM 800 match those predetermined readings then the test socket 58a, 58b is considered to be functioning correctly and the DVM is considered to be properly calibrated.

For example, if the “relay short test” switch 22 is pressed while the dummy relay 70 is inserted in the test socket 58a, 58b, then the red LED 18 will flash. If either of the “Pull-in test” switch 24 or “Contact Release” switch 26 is pressed, then the DVM will read 100. If either of the “NC or NO Voltage Drop” switches 28, 30 are pressed then the meter will read 1000. The user can then remove the dummy relay 70 from the relay connection socket 58a, 58b and select the “cycle test” switch 32. If the relay connection socket 58a, 58b is operating correctly, both yellow LEDs 20a, 20b should illuminate. In addition, it will be appreciated that the yellow LEDs 20a, 20b prove the integrity of the incandescent lamps since if either lamp fails, the LEDs will not illuminate.

If the readings on the DVM 800 indicate that the relay connection socket 58a, 58b or the calibration of the DVM 800 is incorrect then the apparatus is deemed to be faulty and can be returned for repair or replacement.

It will be appreciated that the present invention provides a simple and effective apparatus for performing a number of different test on a relay or the like whilst being portable and simple to use.

To reduce the need for the user or technician to be intimately familiar specifications of different relays to be tested, the apparatus may be advantageously provided with a relay specification card, which can conveniently be attached to the apparatus, which sets out the nominal parameters for different relay types and the expected readings on the DVM. Deviation from the nominal parameters or expected readings gives a clear indication to the technician that the relay is faulty in one or more respects and should be repaired or replaced. The decision-making process is therefore removed from the technician enabling even unskilled users to accurately operate the apparatus.

Relay faults that can be verified using the apparatus include internal short circuits; any failures associated with contact problems, for example high voltage drops; contact contamination (oxidisation) and welded contacts; and over-travel of the relay armature. Advantageously, therefore, positive identification of faulty relays against engineering specifications can be achieved with the ability to leave relays that are functioning correctly in the vehicle. This can result in increased customer satisfaction since the technician can verify the operation of the relay RLT on site and either perform a first-time fix, replace the relay if it is faulty, or establish that it is a different part of the system that is faulty.

Advantageously, the pull in current test and contact release test measures current through the coil which is conveniently displayed in milliamps. Current is monitored since pull-in and release voltages are dependent upon the resistance of the coil CC of the relay RLT which changes with coil temperature. Thus, were the pull-in and contact release tests to measure voltage, rather than current, inconsistent results would be produced.

The simplicity of the apparatus and its use means that a full test can be performed on a relay in less than 1 minute.

It will also be appreciated that the specific details of the circuits shown in the drawings and described above are not intended to be limiting in any way and may be replaced by any electrically equivalent circuitry or by circuitry providing similar functions. For example, the polarity protection circuit 700 may be replaced by a Field Effect Transistor (FET) which turns off if the polarity of the supply is reversed.

It is envisaged that the present invention may be provided with a port 46 for connection to an external PC or other computer or data collector. It will be appreciated by those skilled in the art that the provision of a suitable analogue to digital converter (ADC) would allow connection of the device to, for example, the LPT or RS232 Port of an external computer or data collector.

1. An apparatus for testing an electrical relay, the apparatus comprising:
a portable housing;
an electrical testing circuit within said portable housing for performing a plurality of types of tests on said relay;
a connection arrangement connected to said electrical testing circuit for connecting said electrical testing circuit to said electrical relay; and
a display connected to said electrical testing circuit for displaying the results of said tests.

2. An apparatus as claimed in claim 1, further comprising a switch arrangement connected to said electrical testing circuit for selecting which of said tests are to be performed on said relay.

3. An apparatus as claimed in claim 1, wherein said connection arrangement comprises a multi-core cable connected at one end thereof to said electrical testing circuit via a connector and connectable at the other end to said relay via a conventional relay socket.

4. An apparatus as claimed in claim 3, wherein said connector comprises a multi-pin plug connected to said multi-core cable and a cooperating socket mounted on said housing and connected to said electrical testing circuit.

5. An apparatus as claimed in claim 1, wherein said display comprises a digital volt meter, or digital multi-meter having an LCD display, which is arranged to measure and/or display one or more properties of said relay.

6. An apparatus as claimed in claim 1, further comprising means for connecting said apparatus to a PC or other external computer or data collector.

7. An apparatus as claimed in claim 1, wherein said apparatus is arranged to be powered by a 12 volt electrical power supply.

8. An apparatus as claimed in claim 7, further comprising a power cable for insertion into a cigarette lighter socket of a car or other vehicle.

9. An apparatus as claimed in claim 1, further comprising polarity protection means for protecting said electrical testing circuit and said display from a reverse polarity power supply.

10. An apparatus as claimed in claim 1, wherein said tests include a short circuit test.

11. An apparatus as claimed in claim 10, wherein said short circuit test tests for a short circuit between the coil of said relay and the armature and/or contacts of said relay.

12. An apparatus as claimed in claim 1, wherein said tests include a pull in current test for determining the current at which said relay switches on.

13. An apparatus as claimed in claim 1, wherein said tests include a contact release current test which determines the current at which the relay switches off.

14. An apparatus as claimed in claim 12, wherein said electrical testing circuit is arranged to ramp current through the coil of said relay up or down respectively until said relay switches on or off respectively, whereupon said current is clamped and measured by said display.

15. An apparatus as claimed in claim 1, wherein said tests include a contact voltage drop test for determining the voltage drop over normally open and/or normally closed contacts of said relay.

16. An apparatus as claimed in claim 1, wherein said tests include a cycle test for rapidly switching said relay on or off a predetermined number of times thereby to determine correct repeated operation of said relay.

17. An apparatus as claimed in claim 16, further comprising means for providing a surge of electrical current through said relay when said relay is switched on during said cycle test.

18. An apparatus as claimed in claim 1, wherein said tests include a test for determining over travel of the armature of said relay.

19. An apparatus as claimed in claim 2, further including a remeasure switch on said housing for reperforming said tests without resetting said apparatus or operating said switch arrangement.

20. An apparatus as claimed in claim 1, further comprising for a relay specification card or similar for displaying to a user nominal parameters specification or characteristics of said relay.

21. An apparatus as claimed in claim 1, further comprising means for testing said connection arrangement.

22. An apparatus as claimed in claim 21, wherein said means for testing said connection arrangement comprises a dummy relay arranged to produce predetermined results on said display in response to performing of said tests on said dummy relay.

23. An apparatus for testing an electrical relay, the apparatus comprising:
a portable housing;
electrical testing means within said portable housing for performing a plurality of types of tests on said electrical relay;
connecting means for connecting said relay to said electrical testing means; and
display means for displaying the results of said tests.
